(19) United States
(12) Patent Application Publication
(10) Pub. No.: US 2023/0108710 A1
(43) Pub. Date: Apr. 6, 2023

(54) PHOTOVOLTAIC MODULE WITH PROTECTIVE REGION AND PROTECTION METHOD PHOTOVOLTAIC MODULE

(71) Applicant: TOPICO LOCACOES DE GALPOESE EQUIPAMENTOS PARA INDUSTRIAS S.A., Embu das Artes (BR)

(72) Inventors: LEONARDO AUGUSTO DE CAMPOS, Sao Paulo (BR); ANTONIO CESAR GALHARDI, Jundiai (BR); FERNANDO DE MORAIS GOMEZ, Caieiras (BR)

(21) Appl. No.: 17/794,583

(22) PCT Filed: Jan. 19, 2021
(86) PCT No.: PCT/BR2021/050024

§ 371 Date: Jul. 21, 2022

(30) Foreign Application Priority Data
Jan. 22, 2020 (BR) 102020001381-5

(51) Int. Cl. H01L 31/02; H01L 31/048

(52) U.S. Cl. CPC H01L 31/02008; H01L 31/0481

(57) ABSTRACT

The present invention relates to a flexible infrastructure solution for protecting the cables of flexible photovoltaic panels. The solution comprises a cutout for insertion of the ends of the cables and a cover for the cutout area intended to protect the end of the cables.

### FIELD OF THE INVENTION

The present invention refers to a flexible infrastructure solution, which allows the protection of flexible photovoltaic plate cables.

The solution consists of a cut for insertion of the ends of the cables and a jacket over the region of the cut, thus protecting the ends of the cables.

### BACKGROUND OF THE INVENTION

Power generation systems using photovoltaic plates, installed on roof structures of houses, buildings, sheds and other surfaces, are well known for converting solar radiation into electrical energy.

Photovoltaic plates are typically placed on a support surface, such as a roof, and directed towards the light, and the electrical energy produced must be transmitted through cables that start from the photovoltaic plate. These cables add complexity to the system as it requires proper positioning so that it is not loose and protected from adverse weather conditions, such as wind and rain.

For this reason, there is the need to provide protection to this wiring of the photovoltaic plates to obtain constant power generation.

The patent literature already has some suggestions to solve this problem, however, they differ from the present invention in several aspects.

Documents US 2019/219196 and US 2019/341882 describe devices for managing photovoltaic plate cables to be mounted on support surfaces, such as roofs or rails, thus avoiding contact of the wiring with the external environment.

The present invention differs from these solutions in that it is specific for use on flexible surfaces, while documents US 2019/219196 and US 2019/341882 are directed to more rigid surfaces.

Document US 2019/379322 describes a solution for cable management on roofs composed of Shingle tiles, where the cables are hidden under the photovoltaic plates and between the tiles.

The present invention differs from this solution by being specific for use on flexible surfaces and not on rigid surfaces.

Therefore, the present invention is innovative compared to the current state of the art and even if a specialist were to combine these teachings, the solution proposed by this invention would not be reached.

### SUMMARY OF THE INVENTION

The object of the present invention is a photovoltaic module with a protective zone comprising:
a) At least one photovoltaic plate fixed to the upper area of the flexible membrane;
b) At least one cut in the upper area of the flexible membrane that allows the cables to pass from the photovoltaic plate to the lower area of the flexible membrane; and
c) At least one jacket attached to the upper part of the flexible membrane, covering the entire cut of item b).

An additional object of the present invention is a photovoltaic plate cable protection method comprising the steps of:
a) providing at least one photovoltaic plate fixed to the upper area of the flexible membrane;
b) inserting the cable of at least one photovoltaic plate in the region between the upper part of the flexible membrane and at least one jacket; and
c) inserting the end of at least one cable of at least one photovoltaic plate in at least one cut in the upper area of the flexible membrane.

### BRIEF DESCRIPTION OF THE FIGURES

FIG. 1 shows schematic top and bottom views of a flexible membrane according to the present invention.

FIG. 2 shows a photograph of the upper area of a photovoltaic module with the protection area of the present invention, where the end of the cable is hidden.

FIG. 3 shows a photograph of the lower area of the photovoltaic module of FIG. 2, showing the cutout and the end of the cable.

### DETAILED DESCRIPTION OF THE INVENTION

The following description is intended only to exemplify some of the numerous ways of carrying out the invention, and should not be viewed as limiting the scope of the present invention.

When developing the solution, it was identified that it solves problems related to the integrity of the cables, since they are not exposed to the environment. In addition, the present invention provides advantages such as protection against the infiltration of water that falls on the photovoltaic module, such as rain, which commonly uses the wiring as a guide to infiltrate the electrical system (electrical panels and battery banks) associated with the photovoltaic module, damaging it.

Photovoltaic Module with Protection Region

The photovoltaic module according to the present invention comprises at least one flexible photovoltaic plate glued to a flexible membrane.

Any flexible photovoltaic board known in the art can be used and is within the scope of the present invention. Flexible membranes include, but are not limited to, a vinyl membrane. Other polymeric membranes can be used and are within the scope of the present invention.

The protection zone of the photovoltaic module comprises:
a) At least one photovoltaic plate fixed to the upper area of the flexible membrane;
b) At least one cut in the upper area of the flexible membrane that allows the cables to pass from the photovoltaic plate to the lower area of the flexible membrane; and
c) At least one jacket attached to the upper part of the flexible membrane, covering the entire cut of item b).

In an embodiment according to the present invention, the module comprises a plurality of photovoltaic plates. In another embodiment according to the present invention, the module comprises a plurality of cutouts. In another embodiment according to the present invention, the module comprises a plurality of jackets.

Several configurations can be made with cables, cutouts and jackets, all within the scope of the present invention. Some non-limiting examples of possible configurations are: a jacket that covers a cutout that houses a cable; a jacket that covers a cutout that houses more than one cable; a jacket covering more than one cutout, where each cutout houses one or more cables; more than one jacket, where each jacket covers a cutout that houses a cable; more than one jacket, where each jacket covers a cutout that houses more than one cable; more than one jacket, where each jacket covers more than one cutout that houses one or more cables.

Preferably, the photovoltaic module comprises a jacket that covers a cutout that houses a cable.

This thin-film photovoltaic plate cable access configuration solves at least two problems:
a) vibration of the cable against the canvas (due to the wind, for example) and which, therefore, favors its wear; and
b) prevents the conduction of water into the structure by the cable.

### Photovoltaic Plate Cable Protection Method

The photovoltaic plate cable protection method according to the present invention comprises the steps of:
a) providing at least one photovoltaic plate fixed to the upper area of the flexible membrane;
b) inserting the cable of at least one photovoltaic plate in the region between the upper part of the flexible membrane and at least one jacket; and
c) inserting the end of at least one cable of at least one photovoltaic plate in at least one cut in the upper area of the flexible membrane.

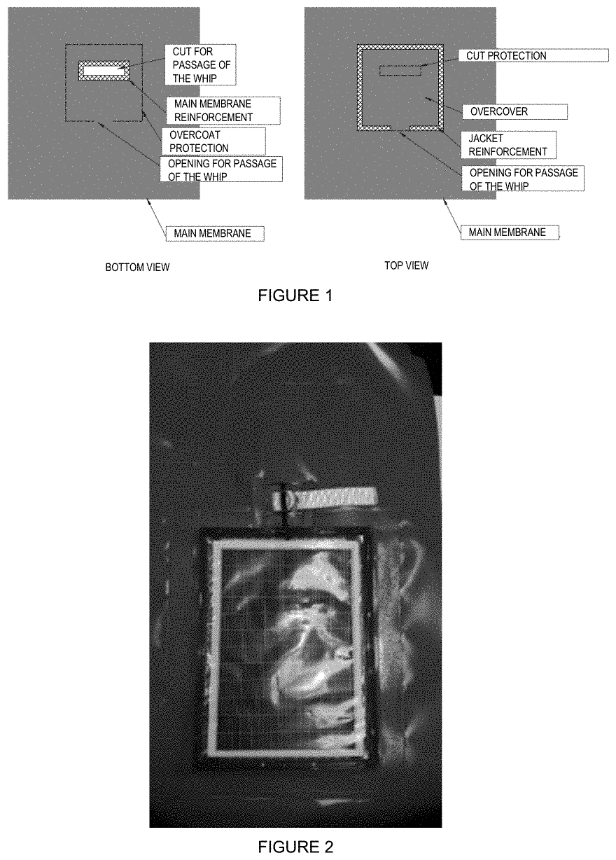

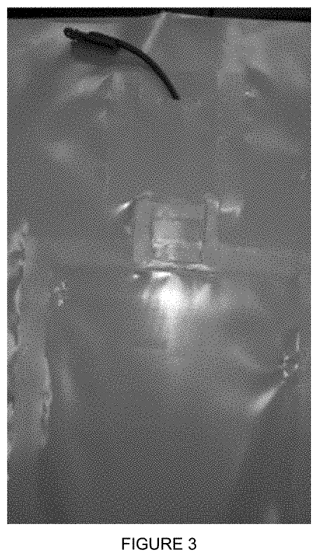

In a preferred embodiment, the method comprises a plurality of photovoltaic modules.
CUT FOR PASSAGE OF THE WHIP
MAIN MEMBRANE REINFORCEMENT
OVERCOAT PROTECTION
OPENING FOR PASSAGE OF THE WHIP BOTTOM VIEW
CUT PROTECTION
OVERCOVER
JACKET REINFORCEMENT
OPENING FOR PASSAGE OF THE WHIP
MAIN MEMBRANE
   TOP VIEW
   FIG. 1
   FIG. 2
   FIG. 3

1. Photovoltaic module with protective region characterized by comprising
a) At least one photovoltaic plate fixed to the upper area of the flexible membrane;
b) At least one cut in the upper area of the flexible membrane that allows the cables to pass from the photovoltaic plate to the lower area of the flexible membrane; and
c) At least one jacket attached to the upper part of the flexible membrane, covering the entire cut of item b).

2. Photovoltaic module, according to claim 1, characterized in that the flexible membrane is a vinyl canvas.

3. Photovoltaic plate cable protection method characterized by comprising the steps of:
a) providing at least one photovoltaic module as defined in claim 1 or 2;
b) inserting the cable of at least one photovoltaic plate in the region between the upper part of the flexible membrane and at least one jacket; and
c) inserting the end of at least one cable of at least one photovoltaic plate in at least one cut in the upper area of the flexible membrane.

4. Method, according to claim 3, characterized in that the flexible support membrane is a vinyl canvas.
